(19) United States
(12) Patent Application Publication
(10) Pub. No.: US 2025/0248113 A1
(43) Pub. Date: Jul. 31, 2025

(54) INTEGRATED CIRCUIT DEVICE AND MANUFACTURING METHOD THEREOF

(71) Applicants: Taiwan Semiconductor Manufacturing Company, Ltd., Hsinchu (TW); National Taiwan University, Taipei (TW)

(72) Inventors: Chien-Te Tu, Hsinchu City (TW); Bo-Wei HUANG, New Taipei City (TW); Chee-Wee LIU, Taipei City (TW)

(73) Assignees: Taiwan Semiconductor Manufacturing Company, Ltd., Hsinchu (TW); National Taiwan University, Taipei (TW)

(21) Appl. No.: 18/423,731

(22) Filed: Jan. 26, 2024

(51) Int. Cl. H01L 27/088; H01L 21/02; H01L 21/3105; H01L 21/324; H01L 21/8234; H01L 21/8238

(52) U.S. Cl. CPC H10D 84/83; H01L 21/02532; H01L 21/31056; H01L 21/324; H10D 84/0144; H10D 84/0186; H10D 84/038

(57) ABSTRACT

A method for manufacturing an integrated circuit device is provided. The method includes depositing an epitaxial stack over a substrate, wherein the epitaxial stack comprises a bottom epitaxial stack, a sacrificial semiconductor layer over the bottom epitaxial stack, a top epitaxial stack over the sacrificial semiconductor layer, the bottom epitaxial stack comprises a bottom semiconductor layer and a bottom doped sacrificial layer, and the top epitaxial stack comprises a top semiconductor layer and a top doped sacrificial layer; replacing first portions of the doped bottom sacrificial layer, the sacrificial semiconductor layer, and the top doped sacrificial layer with a gate structure; and replacing a second portion of the sacrificial semiconductor layer with a dielectric isolation layer.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-5B illustrate a method of manufacturing an integrated circuit device at various stages in accordance with some embodiments.

FIGS. 6A-7B illustrate a method of manufacturing an integrated circuit device at various stages in accordance with some embodiments.

FIGS. 8A-20B illustrate a method of manufacturing an integrated circuit device at various stages in accordance with some embodiments.

FIGS. 21A and 21B illustrates p-type dopant profiles and levels in an epitaxial stack respectively before and after an annealing process in accordance with some embodiments.

FIGS. 22-25 illustrate a method of manufacturing an integrated circuit device at various stages in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a GAA device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

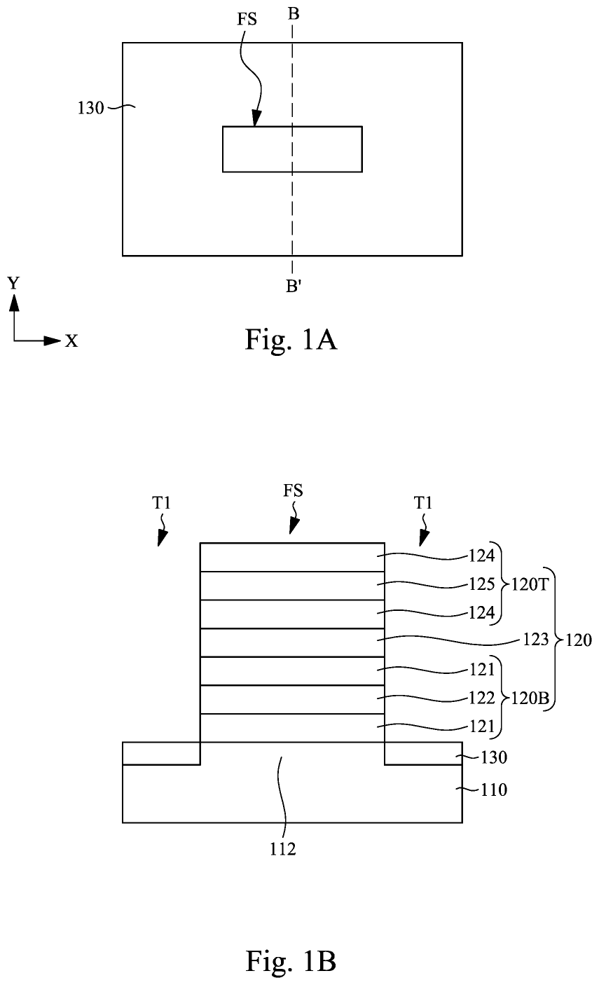

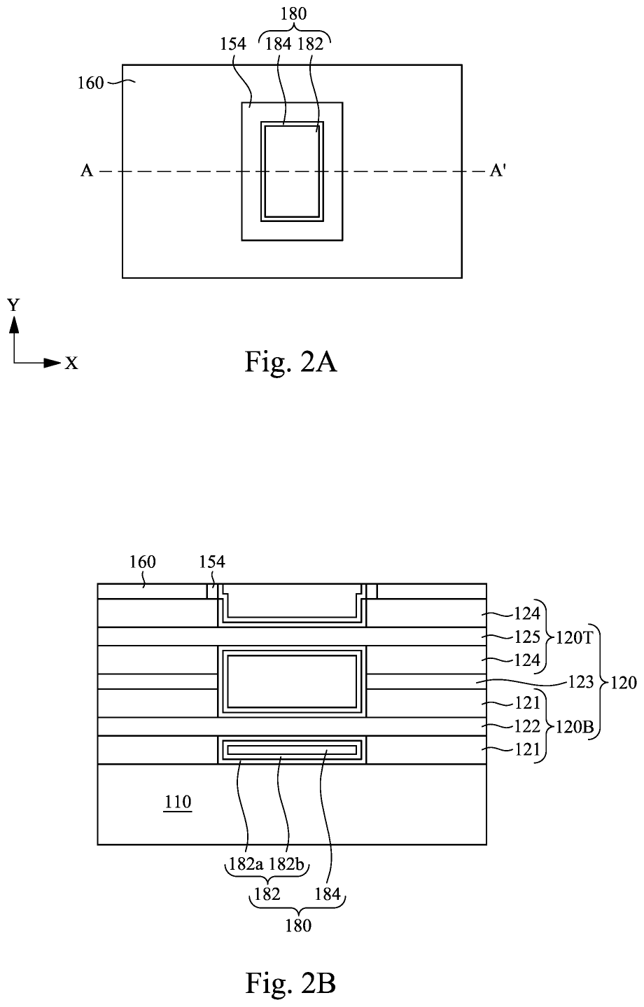

FIGS. 1A-5B illustrate a method of manufacturing an integrated circuit device at various stages in accordance with some embodiments. FIGS. 1A, 2A, 3A, 4A, and 5A are top views of the integrated circuit device at various stages in accordance with some embodiments. FIG. 1B is a cross-sectional view of the integrated circuit device taken along a line B-B of FIG. 1A. FIGS. 2B, 3B, 4B, and 5B are cross-sectional views of the integrated circuit device respectively taken along line A-A of FIGS. 2A, 3A, 4A, and 5A. It is understood that additional steps may be provided before, during, and after the steps shown in FIGS. 1A-5B, and some of the steps described below can be replaced or eliminated for additional embodiments of the method. The order of the operations/processes may be interchangeable.

Reference is made to FIGS. 1A and 1B. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes a bottom epitaxial stack 120B, an sacrificial semiconductor layer 123 over the bottom epitaxial stack 120B, and a top epitaxial stack 120T over the sacrificial semiconductor layer 123, in which each of the bottom and top epitaxial stacks 120B and 120A includes semiconductor sacrificial layers and one or more semiconductor channel layers and alternatively arranged with the semiconductor sacrificial layers. For example, in the present embodiments, the bottom epitaxial stack 120B includes a lower semiconductor sacrificial layer 121, a semiconductor channel layer 122 over the lower semiconductor sacrificial layer 121, and an upper semiconductor sacrificial layer 121 over the semiconductor channel layer 122. For example, the top epitaxial stack 120T includes a lower semiconductor sacrificial layer 124, a semiconductor channel layer 125 over the lower semiconductor sacrificial layer 124, and an upper semiconductor sacrificial layer 124 over the semiconductor channel layer 125. In some embodiments, the semiconductor layers 121-125 may include suitable semiconductor material, such as group-IV semiconductor (e.g., Si, Ge, Sn, SiGe, GeSn), III-V semiconductor (e.g., GaAs), the like, or the combination thereof. The thickness of any two or more of the semiconductor layers 121-125 may be different from each other.

In some embodiments, the material of the semiconductor layer 122 is selected for serving as a p-type channel for a p-type transistor, and the material of the semiconductor layer 125 is selected for serving as a n-type channel for a n-type transistor. In some alternative embodiments, the material of the semiconductor layer 122 is selected for serving as a n-type channel for a n-type transistor, and the material of the semiconductor layer 125 is selected for serving as a p-type channel for a p-type transistor. The layers 121, 122, and 123 may have different semiconductor compositions from each other, and the layers 124, 125, and 123 may have different semiconductor compositions from each other. For example, the channel semiconductor layers 122 and 125 are SiₓGe₁₋ₓ, the sacrificial semiconductor layers 121 and 124 are Si_{y}Ge_{1-y}, and the sacrificial semiconductor layer 123 is Si_{z}Ge_{1-z}, in which x, y, z are in a range from 0 to 1, and x>y>z. In some other embodiments, the channel semiconductor layers 122 and 125 are SiₓGe₁₋ₓ, the sacrificial semiconductor layers 121 and 124 are Si_{y}Ge_{1-y}, and the sacrificial semiconductor layer 123 is Si_{z}Ge_{1-z}, in which x, y, z are in a range from 0 to 1, and x>z>y.

The semiconductor channel layers 122 and 125 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 122 and 125 may be referred to as semiconductor channels in the context. The use of the channel layers 122 and 125 to define a channel or channels of a device is further discussed below.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 121-125 include suitable crystalline semiconductor material, such as Si, Ge, Sn, SiGe, GeSn, III-V semiconductor, the like, or the combination thereof. In some embodiments, the semiconductor layers 122 and 125 are intrinsic semiconductor layers. For example, the semiconductor layers 122 and 125 are substantially dopant-free (i.e., having an extrinsic dopant concentration from about 0 cm⁻³ to about 1×10¹⁸ cm⁻³), where for example, no intentional doping is performed during the epitaxial growth process. In some embodiments where a PMOS is stacked over a NMOS, the semiconductor sacrificial layers 121 may be intentionally doped with n-type dopants (e.g., phosphorus), for example, with a dopant concentration from about 1×10¹⁸ cm⁻³ to about 1×10²² cm⁻³, and the semiconductor sacrificial layers 124 may be intentionally doped with p-type dopants (e.g., boron), for example, with a dopant concentration from about 1×10¹⁸ cm⁻³ to about 1×10²² cm⁻³. In some embodiments where a NMOS is stacked over a PMOS, the semiconductor sacrificial layers 121 may be intentionally doped with p-type dopants (e.g., boron), for example, with a dopant concentration from about 1×10¹⁸ cm⁻³ to about 1×10²² cm⁻³, and the semiconductor sacrificial layers 124 may be intentionally doped with n-type dopants (e.g., phosphorus), for example, with a dopant concentration from about 1×10¹⁸ cm⁻³ to about 1×10²² cm⁻³. The sacrificial layers 123 may be substantially dopant-free or intentionally doped with n-type dopants or p-type dopants.

It is noted that one semiconductor channel layer 122 and two semiconductor sacrificial layers 121 are alternately arranged, and one semiconductor channel layer 125 and two semiconductor sacrificial layers 124 are alternately arranged as illustrated in FIG. 1B, which is for illustrative purposes only and not intended to be limiting beyond what is specifically recited in the claims. It can be appreciated that any number of semiconductor channel layers 122 can be formed in the bottom epitaxial stack 120B, and any number of semiconductor channel layers 125 can be formed in the top epitaxial stack 120T. In some embodiments, the number of the semiconductor channel layers 122 is between 1 and 8, and the number of the semiconductor channel layers 125 is between 1 and 8. For example, in FIGS. 1A and 1B, the number of the semiconductor channel layers 122 is 1, and the number of the semiconductor channel layers 125 is 1.

At least one semiconductor fin FS extending from the substrate 110 is formed. The semiconductor fin FS may extend substantially along a direction X. In various embodiments, each of the fins FS includes a substrate portion 112 formed from the substrate 110 and portions of each of the epitaxial layers of the epitaxial stack 120 including epitaxial layers 121-125.

The fins FS may be fabricated using suitable processes including photolithography and etch processes. The photolithography process may include forming a photoresist layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions, through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

An isolation structure 130 is formed in the trench T1 between the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material, followed by an etching back process. Through the etching back process, a top surface of the isolation structure 130 may be level with or lower than a bottom surface of the epitaxial stack 120. In some alternatively embodiments, the top surface of the isolation structure 130 may be higher than the bottom surface of the epitaxial stack 120.

Reference is made to FIGS. 2A and 2B. A gate structure 180 is formed to surround each of the nanosheets (e.g., the semiconductor channel layers 122 and 125). The gate structures GS may be final gates of GAA FETs. The final gate structure may be a high-k/metal gate stack, however other compositions are possible. In some embodiments, the gate structure 180 forms the gate associated with the channel region of the semiconductor channel layer 122 and the channel region of the semiconductor channel layer 125. For example, the high-k/metal gate structures 180 are formed within the openings/spaces provided by the release of the semiconductor channel layers 122 and 125. In some embodiments, the high-k/metal gate structure 180 wrapping around the channel region of the semiconductor channel layer 122 is continuously connected with the high-k/metal gate structure 180 wrapping around the channel region of the semiconductor channel layer 125.

In various embodiments, the high-k/metal gate structure 180 includes a gate dielectric layer 182 and a gate metal layer 184 formed around the gate dielectric layer 182. Formation of the high-k/metal gate structures 180 may include one or more deposition processes (e.g., ALD, CVD, physical vapor deposition (PVD), the like, or the combination thereof) to form various gate materials, resulting in the high-k/metal gate structures GS. In some embodiments, a dummy gate structure, gate spacers 154, and an interlayer dielectric layer 160 are formed first, and a gate replacement process is performed to replace the dummy gate structure with the high-k/metal gate structure 180.

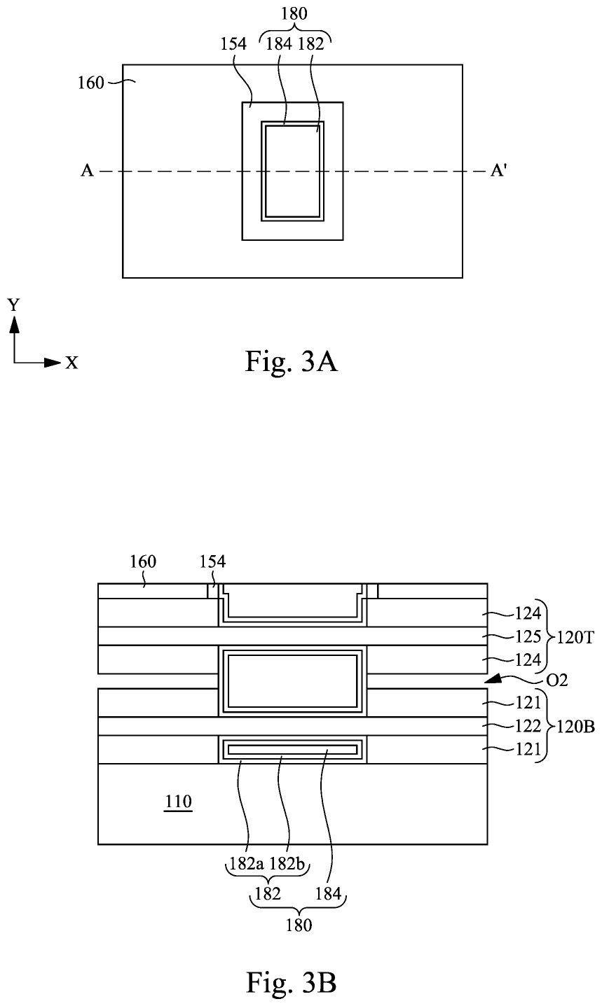

Reference is made to FIGS. 3A and 3B. A selective etching process is performed to remove the sacrificial semiconductor layer 123. In some embodiments, the selective etching process may etch materials of the sacrificial semiconductor layer 123 at a faster rate than etch materials of the layers 121, 122, 124, and 125, thus resulting in openings/spaces O2 between the bottom epitaxial stack 120B and the top epitaxial stack 120T. The selective etching process may include a dry etch, a wet etch, or the combination thereof. In the present embodiments, the selective etching process may use a suitable etch recipe for removing the portions of the sacrificial semiconductor layer 123 (forming the opening O2) without substantially damaging the layers 121, 122, 124, and 125. For example, the selective etching process may be a dry etching process using the fluorine-based gas (e.g. SF₆).

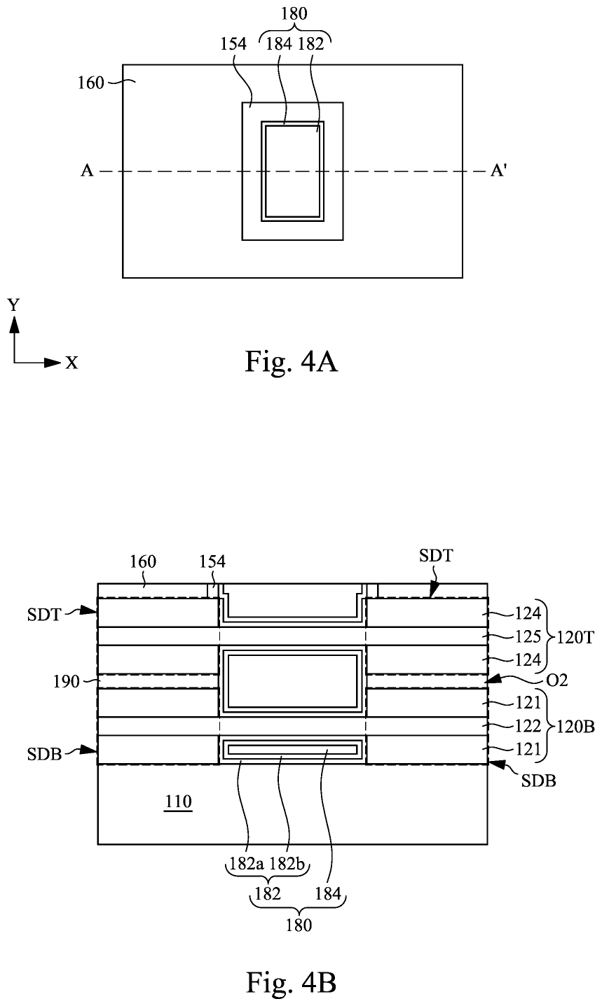

Reference is made to FIGS. 4A and 4B. A dielectric isolation layer 190 is deposited into the openings O2. The dielectric isolation layer 190 may include suitable dielectric materials, such as silicon oxide, silicon oxynitride, and silicon nitride. The deposition process may include ALD, CVD, the like, or the combination thereof. In some embodiments, regions of the bottom epitaxial stack 120B on opposite sides of the gate structures 180 may form source/drain regions SDB of a bottom transistor, and regions of the top epitaxial stack 120T on opposite sides of the gate structures 180 may form source/drain regions SDT of a top transistor. With the presence of the dielectric isolation layer 190, the source/drain regions SDB and SDT of the two stacked transistors can be electrically isolated from each other and controlled independently.

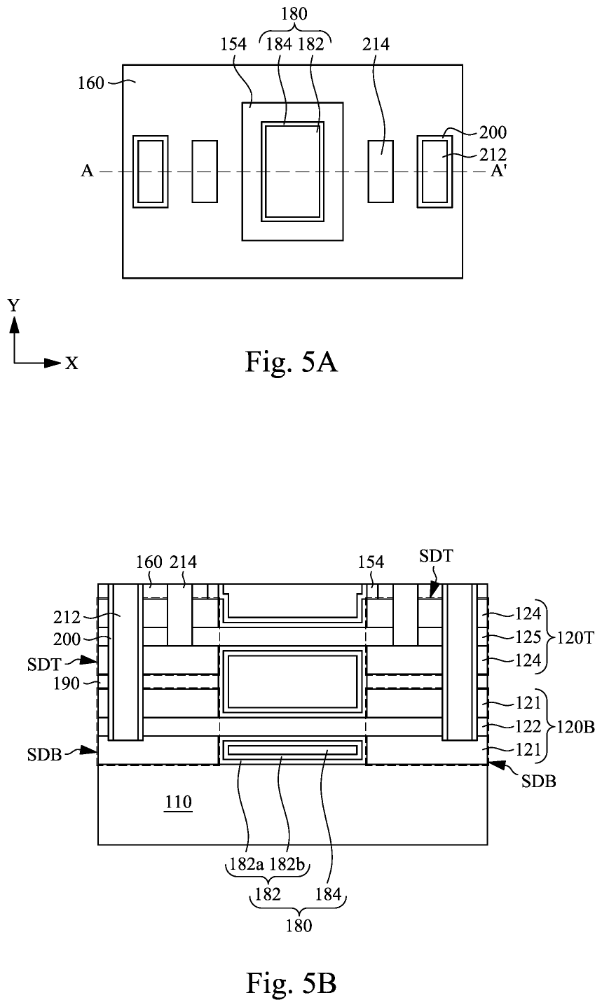

Reference is made to FIGS. 5A and 5B. Contact plugs 212 and 214 may be formed through the interlayer dielectric layer 160, and in contact with the source/drain regions SDB and SDT of the two stacked transistors, respectively. Formation of the contact plugs 212 may include etching holes/openings through the layers 160, 124, 125, and 190 to expose the source/drain regions SDB, and depositing a conductive material into the holes/openings, followed by a chemical mechanical planarization (CMP) process performed to excess conductive material from the holes/openings after depositing the conductive material. In some embodiments, prior to depositing the conductive material, a dielectric barrier layer 200 is formed in the holes/openings through the layers 160, 124, 125, and 190 for isolating the conductive material from the source/drain regions SDB. Formation of the dielectric barrier layer 200 may include depositing a suitable dielectric material (e.g., silicon nitride, silicon oxynitride, the like, or the combination thereof) into the holes/openings, followed by an etching process to remove a bottom portion of the dielectric barrier layer 200, thereby exposing the source/drain regions SDB. Similarly, formation of the contact plugs 214 may include etching holes/openings through the layers 160 to exposed the source/drain regions SDT, and depositing a conductive material into the holes/openings, followed by a CMP process performed to excess conductive material from the holes/openings after depositing the conductive material. In some embodiments, for reducing capacitance, the contact plugs 214 are closer to the gate structure 180 than the contact plugs 212 are.

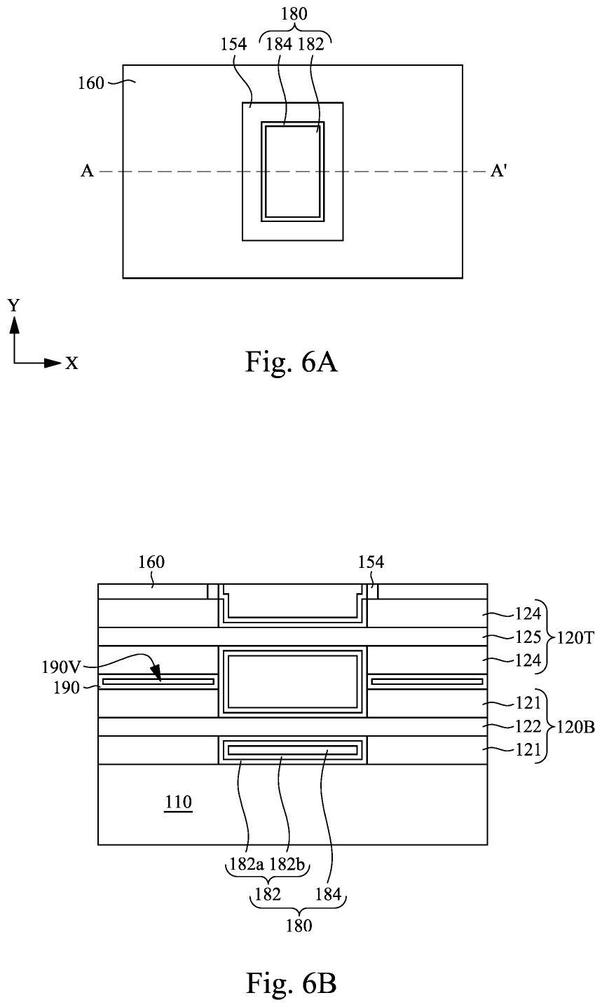

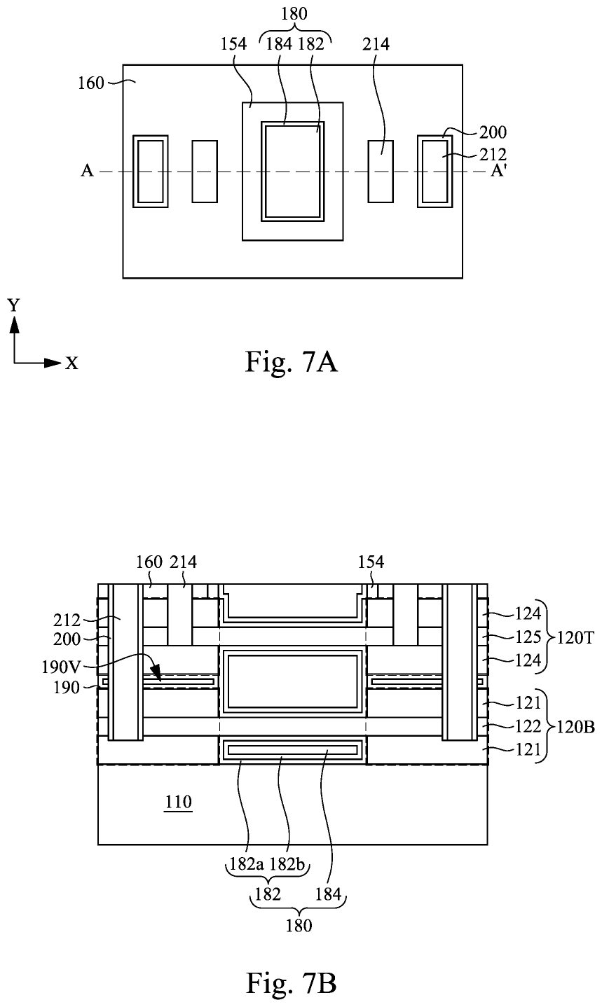

FIGS. 6A-7B illustrate a method of manufacturing an integrated circuit device at various stages in accordance with some embodiments. FIGS. 6A and 7A are top views of the integrated circuit device at various stages in accordance with some embodiments. FIGS. 6B and 7B are cross-sectional views of the integrated circuit device taken along line A-A of FIGS. 6A and 7A. Details of the present embodiments are similar to those illustrated in FIGS. 6A-7B, except that the dielectric isolation layer 190 has a void 190V therein.

Reference is made to FIGS. 6A and 6B. The dielectric isolation layer 190 is deposited into the opening O2. The dielectric isolation layer 190 may include suitable dielectric materials, such as silicon oxide, silicon oxynitride, and silicon nitride, deposited by ALD, CVD, the like, or the combination thereof. The deposited dielectric materials in the opening O2 may merge and form one or voids 190V. Thus, the formed dielectric isolation layer 190 has the voids 190V therein. For example, the formed dielectric isolation layer 190 have a bottom portion 192 adjacent the bottom epitaxial stack 120B, a top portion 194 adjacent the top epitaxial stack 120T, a side portion 196 adjacent the gate structure 180, and a side portion 198 away from the gate structure 180, in which the bottom portion 192, the top portion 194, and the side portions 196 and 198 surround the void 190V. The dielectric isolation layer 190 having the voids 190V may space the source/drain regions SDB and SDT of the two stacked transistors from each other. As a result, the source/drain regions SDB and SDT of the two stacked transistors can be electrically isolated from each other and controlled independently.

Reference is made to FIGS. 7A and 7B. Contact plugs 212 and 214 may be formed through the interlayer dielectric layer 160, and in contact with the source/drain regions SDB and SDT of the two stacked transistors, respectively. Formation of the contact plugs 212 may include etching holes/openings through the layers 160, 124, 125, and 190 to expose the source/drain regions SDB, forming dielectric barrier layers 200 in the holes/openings, and depositing a conductive material into the holes/openings, followed by a CMP process performed to excess conductive material from the holes/openings after depositing the conductive material. Etching holes/openings through the layers 160, 124, 125, and 190 may expose the void(s) 190V in the dielectric isolation layer 190. Formation of the dielectric barrier layer 200 may include depositing a suitable dielectric material (e.g., silicon nitride, silicon oxynitride, the like, or the combination thereof) into the opening, followed by an etching process to remove a bottom portion of the dielectric barrier layer 200, thereby exposing the source/drain regions SDB. The formed dielectric barrier layers 200 may seal the void(s) 190V in the dielectric isolation layer 190, without filling up the void(s) 190V in the dielectric isolation layer 190. In some embodiments, the dielectric barrier layers 200 may not substantially extend into the bottom and top portions of the dielectric isolation layer 190. In some alternative embodiments, the dielectric barrier layers 200 may have portions extending into the bottom and top portions of the dielectric isolation layer 190. In some alternative embodiments, the dielectric barrier layers 200 may fill up the void(s) 190V in the dielectric isolation layer 190. Formation of the contact plug 214 may be similar to those illustrated in FIGS. 5A and 5B, and thereto not repeated herein. Other details of the present embodiment are omitted herein.

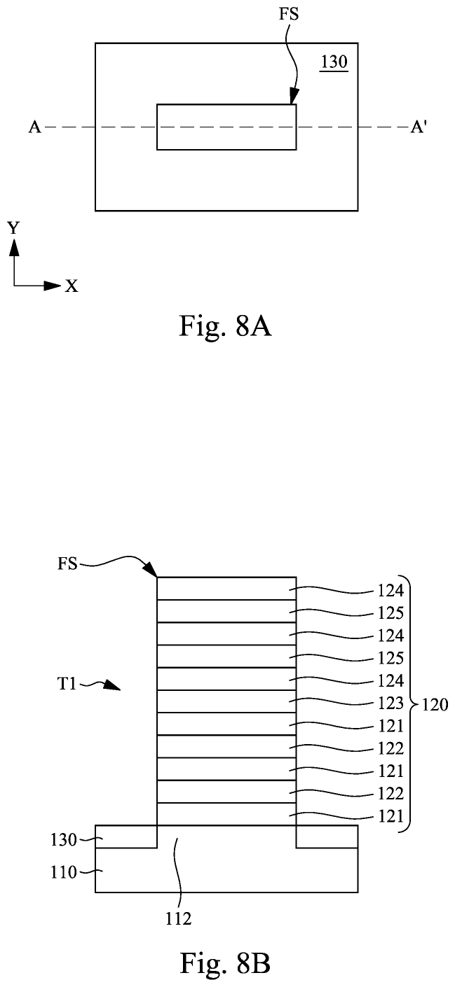

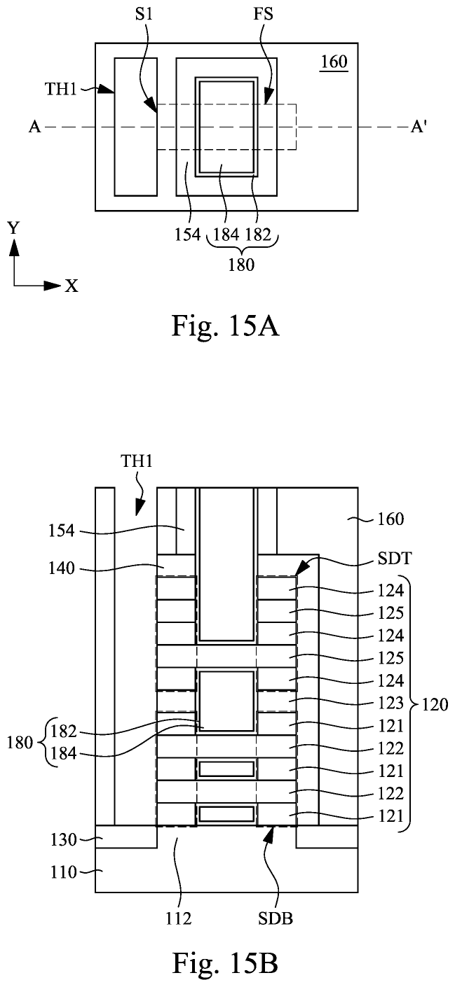

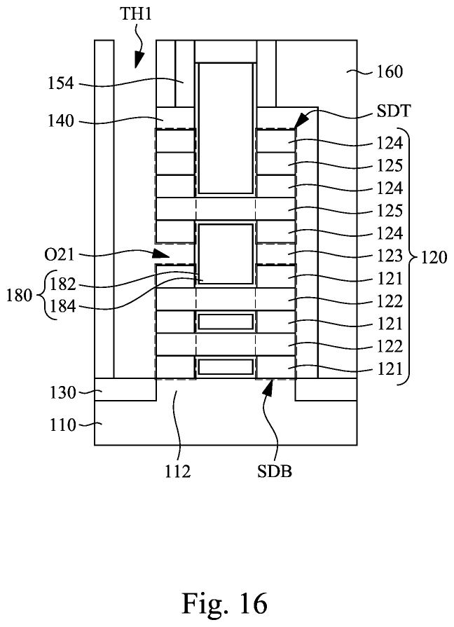

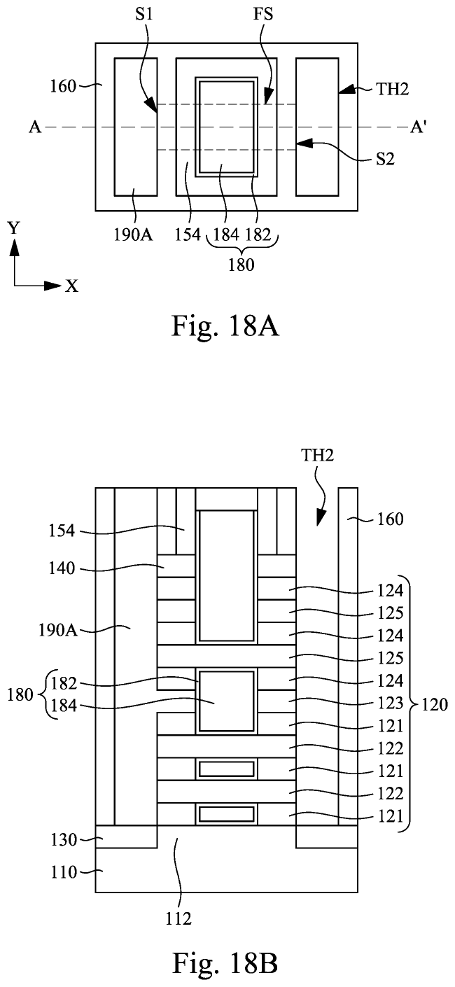

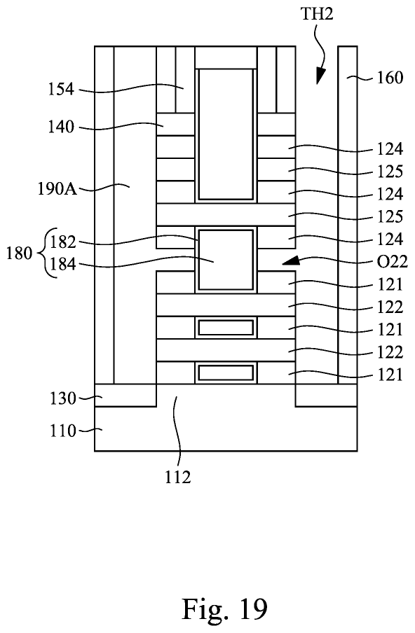

FIGS. 8A-20B illustrate a method of manufacturing an integrated circuit device at various stages in accordance with some embodiments. FIGS. 8A, 9A, 10A, 11A, 12A, 13A, 14A, 15A, 17A, 18A, and 20A are top views of the integrated circuit device at various stages in accordance with some embodiments. FIGS. 8B, 9B, 10B, 11B, 12B, 13B, 14B, 15B, 17B, 18B, and 20B are cross-sectional views of the integrated circuit device respectively taken along line A-A of FIGS. 8A, 9A, 10A, 11A, 12A, 13A, 14A, 15A, 17A, 18A, and 20A. FIGS. 16 and 19 are cross-sectional views of the integrated circuit device taken along the same line as the line A-A of FIGS. 15A and 18A. It is understood that additional steps may be provided before, during, and after the steps shown in FIGS. 8A-20B, and some of the steps described below can be replaced or eliminated for additional embodiments of the method. The order of the operations/processes may be interchangeable.

Reference is made to FIGS. 8A and 8B. As illustrated in FIGS. 1A and 1B, an epitaxial stack 120 is formed over a substrate 110. The epitaxial stack 120 includes a bottom epitaxial stack 120B, an sacrificial semiconductor layer 123 over the bottom epitaxial stack 120B, and a top epitaxial stack 120T over the sacrificial semiconductor layer 123. For example, in the present embodiments, the bottom epitaxial stack 120B includes three semiconductor sacrificial layers 121 and two semiconductor channel layer 122 alternatively arranged over the substrate 110. For example, the top epitaxial stack 120T includes three semiconductor sacrificial layers 124 and two semiconductor channel layers 125 alternatively arranged over the sacrificial semiconductor layer 123. The layers 121, 122, and 123 may have different semiconductor compositions from each other, and the layers 124, 125, and 123 may have different semiconductor compositions from each other. For example, the channel semiconductor layers 122 and 125 are SiₓGe₁₋ₓ, the sacrificial semiconductor layers 121 and 124 are Si_{y}Ge_{1-y}, and the sacrificial semiconductor layer 123 is Si_{z}Ge_{1-z}, in which x, y, z are in a range from 0 to 1, and x>y>z. In some embodiments, the thickness of any two or more of the semiconductor layers 121-125 may be different from each other. And, the thickness of the semiconductor layers 121/122/124/125 may be different from each other.

At least one semiconductor fin FS extending from the substrate 110 is formed. The semiconductor fin FS may extend substantially along a direction X. In various embodiments, each of the fins FS includes a substrate portion 112 formed from the substrate 110 and portions of each of the epitaxial layers of the epitaxial stack 120 including epitaxial layers 121-125. And, an isolation structure 130 is formed in the trench T1 between the fins FS.

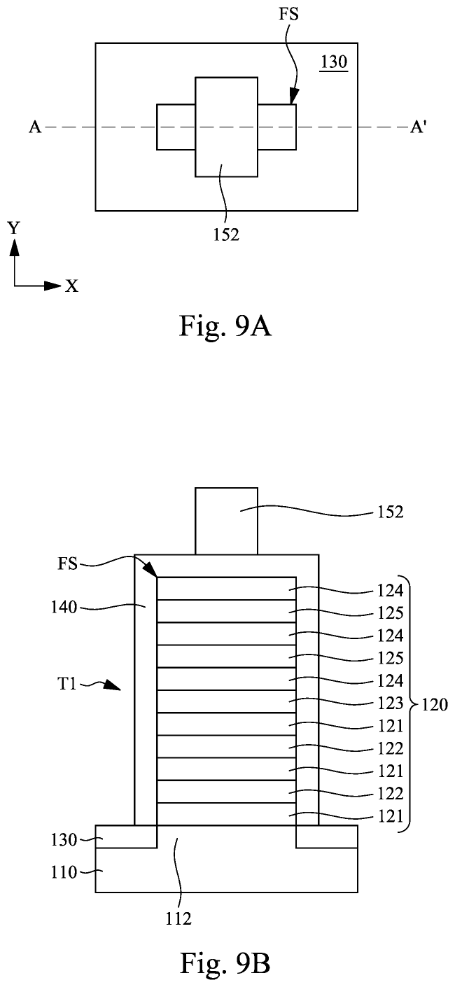

Reference is made to FIGS. 9A and 9B. A dielectric layer 140 is formed over the fins FS, and one or more dummy gate electrode 152 are formed over the dielectric layer 140 and the fins FS. The dielectric layer 140 may include one or more layers of dielectric material, such as silicon oxide, silicon nitride, a high-k dielectric material, and/or other suitable dielectric material. The dielectric layer 140 may also be referred to as a dummy dielectric layer or a sacrificial dielectric layer in the context. In some embodiments, the dielectric layer 140 may be deposited by a CVD process, a sub-atmospheric CVD (SACVD) process, a FCVD process, an ALD process, a PVD process, or other suitable process. In some embodiments, the dummy gate electrode 152 includes polycrystalline silicon (polysilicon). The dummy gate electrode 152 may be formed by first depositing a gate electrode layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the gate electrode layer, the fins FS are partially exposed on opposite sides of the dummy gate structure 152.

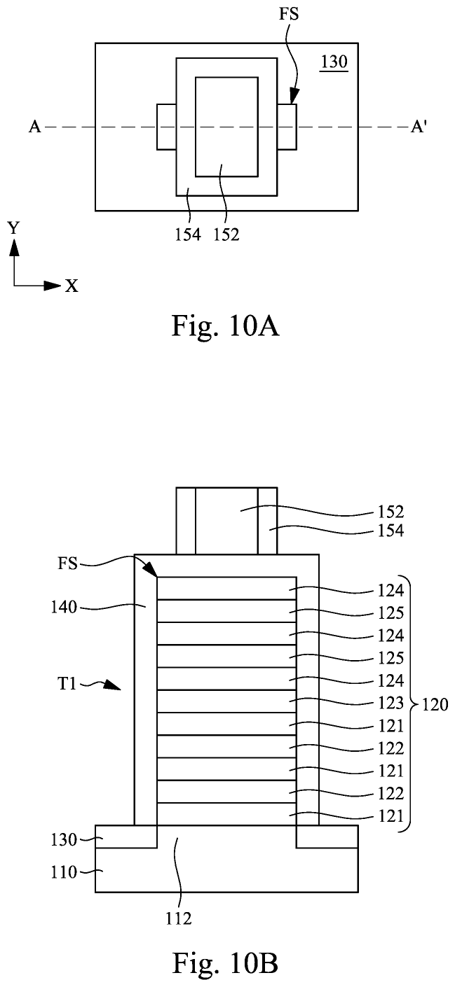

Reference is made to FIGS. 10A and 10B. Gate spacers 154 are formed on opposite sidewalls of the dummy gate electrode 152. The gate spacer 154 may be made of a dielectric material such as silicon oxide, silicon nitride, silicon carbide, silicon oxynitride, SiCN, silicon oxycarbide, SiOCN, and/or combinations thereof. The gate spacer 154 can be formed in a self-aligned method. For example, the gate spacers 154 may be formed by first depositing one or more conformal spacer material layers and subsequently etching back the one or more spacer material layers to form gate spacers 154. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 154 on the vertical surfaces, such as the sidewalls of the dummy gate structures 152. The formed spacer 154 may include a single layer or multiple layers.

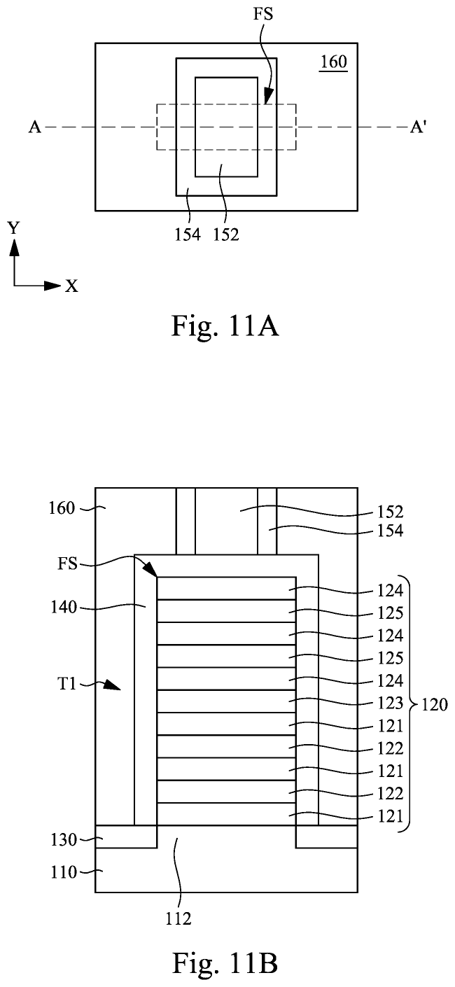

Reference is made to FIGS. 11A and 11B. An interlayer dielectric (ILD) layer 160 is formed over the structure of FIGS. 10A and 10B. In some embodiments, the ILD layer 160 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 160 may be deposited by a CVD process or other suitable deposition technique. The ILD layer 160 may fill up the trenches between the fins FS. After the deposition of the ILD layer 160, a CMP process may be performed to remove a top portion of the ILD layer 160, thereby exposing a top surface of the dummy gate electrode 152. In some embodiments, the CMP process may stop when a top surface of the dummy gate electrode 152 is exposed.

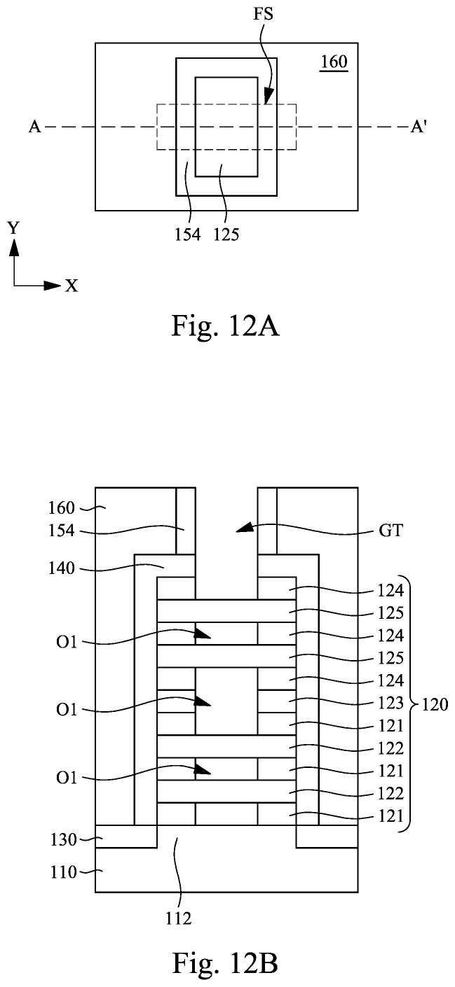

Reference is made to FIGS. 12A and 12B. The dummy gate electrode 152 (referring to FIGS. 11A and 11B) is removed, followed by removing portions of the sacrificial layers 121 and 124 below the dummy gate electrode 152 (referring to FIGS. 11A and 11B). In the illustrated embodiments, the dummy gate electrode 152 (referring to FIGS. 11A and 11B) are removed by using a selective etching process (e.g., selective dry etching, selective wet etching, or a combination thereof) that etches the materials in dummy gate electrode 152 (referring to FIGS. 11A and 11B) at a faster etch rate than it etches other materials (e.g., gate spacers 154 and the dielectric layer 140), thus resulting in a gate trench GT between corresponding gate spacers 154 and exposing the dielectric layer 140. The dielectric layer 140 exposed by the gate trench GT may be etched and removed by a suitable etching process, thereby exposing the topmost sacrificial layer 124 of the epitaxial stack 120.

Subsequently, portions of the sacrificial layers 124, 123, and 121 in the channel region below the gate trench GT are etched by using another selective etching process that etches the sacrificial layers sacrificial layers 124, 123, and 121 at a faster etch rate than it etches the semiconductor layers 125 and 122, thus forming openings/spaces O1 between neighboring semiconductor layers 125 and 122. In this way, portions of the semiconductor layers 122 and 125 in the channel region below the gate trench GT become nanosheets suspended over the substrate 110. This step is also called a channel release process. At this interim processing step, the openings/spaces O1 surrounding the nanosheets 122 and 125 may be filled with ambient environment conditions (e.g., air, nitrogen, etc). In some embodiments, the nanosheets 122 and 125 can be interchangeably referred to as nanowires, nanoslabs and nanorings, depending on their geometry.

In some embodiments, the sacrificial layers 124, 123, and 121 are removed by using a selective dry etching process. In some embodiments, the sacrificial layers 124, 123, and 121 are SiGe and the semiconductor layers 125 and 122 are silicon allowing for the selective removal of the sacrificial layers 124, 123, and 121. In some embodiments, the selective dry etching may use fluorine-based gas (e.g. SF₆), chloride-based gases (e.g., CF₄, C₄F₈), the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until portions of the sacrificial layers 124, 123, and 121 below the gate trench GT are removed. Moreover, because oxidation rate of Si is much lower (sometimes 30 times lower) than oxidation rate of SiGe, the semiconductor layers 125 and 122 may remain substantially intact during the channel release process.

In some embodiments, the selective etching process may use the same etch recipe for removing the portions of the sacrificial layers 124, 123, and 121 without substantially damaging the semiconductor layers 125 and 122. For example, the selective etching process may be a dry etching process using the fluorine-based gas (e.g. SF₆). The selective etching process may be a (substantially) isotropic etching process. For example, the selective etching process may use fluorine-based plasma without substrate bias for substantially isotopically etching materials. With the isotropic etching process, plasma can laterally etch materials below the semiconductor layers 125 and 122.

In some alternative embodiments, the removal of the portions of the sacrificial layers 124 may be separated from the removal of the portions of the semiconductor sacrificial layers 121. For example, a first selective etching process may use a first etch recipe for removing the portions of the sacrificial layers 124 (forming upper openings O1), and a second selective etching process may use a second etch recipe for removing the portions of the semiconductor sacrificial layers 121 (forming lower openings O1), in which the first etch recipe is different from the second etch recipe.

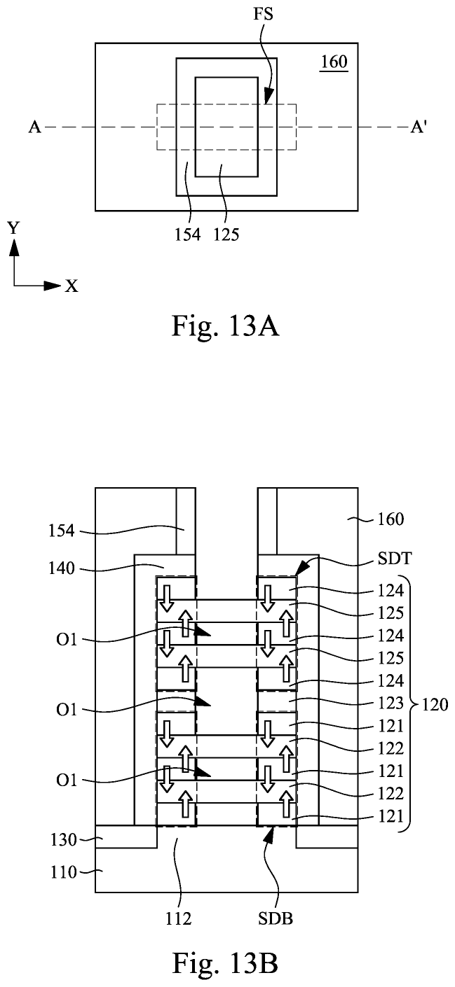

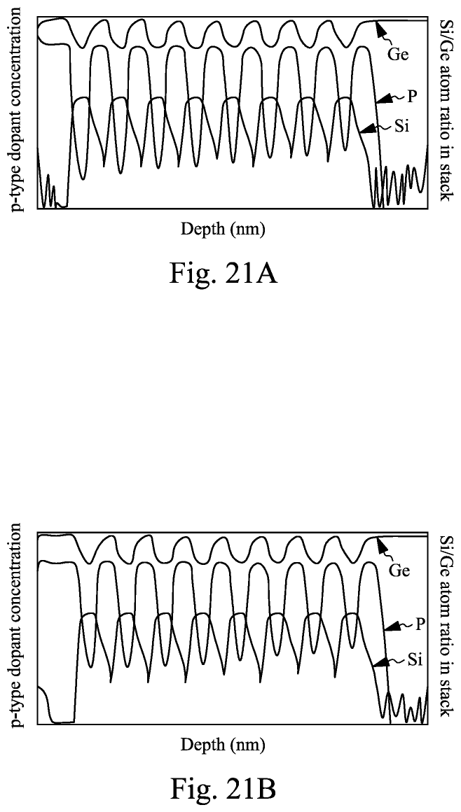

Reference is made to FIGS. 13A and 13B. An annealing process is performed to drive dopant diffusion and activation for low source/drain resistance. Through the annealing process, dopants in remaining portions of the sacrificial layers 121 are diffused in to edge portions of the semiconductor layers 122, thereby forming source/drain region SDB. Also, through the annealing process, dopants in remaining portions of the sacrificial layers 124 are diffused in to edge portions of the semiconductor layers 125, thereby forming source/drain region SDT. Stated differently, the annealing process is performed to transform a second portion of the doped sacrificial layer 121 and a peripheral region of the semiconductor layer 122 into a source/drain region SDB and transform a second portion of the doped sacrificial layer 124 and an peripheral region of the semiconductor layer 125 into a top source/drain region SDT. The diffusion behavior is further illustrated in FIGS. 21A and 21B later. Since the doped sacrificial layers in the channel region are already removed in FIGS. 12A and 12B, the semiconductor layers 125 and 122 in the channel region can remain substantially intrinsic, for example, substantially dopant-free (i.e., having an extrinsic dopant concentration from about 0 cm⁻³ to about 1×10¹⁸ cm⁻³).

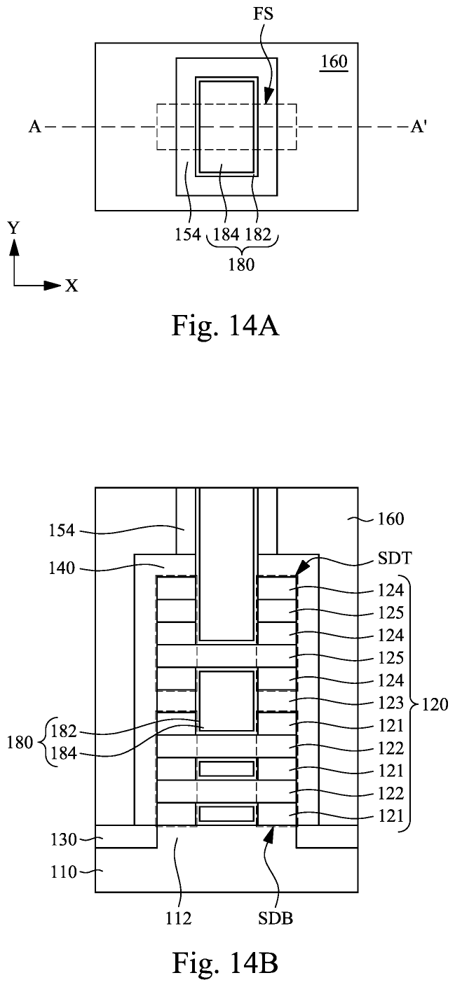

Reference is made to FIGS. 14A and 14B. Replacement gate structures 180 are respectively formed in the gate trenches GT to surround each of the suspended nanosheets 122 and 125 suspended in the gate trenches GT. The gate structures 180 may be final gates of GAA FETs. The final gate structure may be a high-k/metal gate stack, however other compositions are possible. In some embodiments, each of the gate structures 180 forms the gate associated with the multi-channels provided by the plurality of nanosheets 122 and 125. For example, the high-k/metal gate structures 180 are formed within the openings/spaces O1 provided by the release of nanosheets 122 and 125. The high-k/metal gate structures 180 may be between the source/drain region SDB and between the source/drain region SDT.

In various embodiments, the high-k/metal gate structure 180 includes a gate dielectric layer 182 formed around the nanosheets 122 and 125 and a gate metal layer 184 formed around the gate dielectric layer 182 and filling a remainder of gate trenches GT. Formation of the high-k/metal gate structures 180 may include one or more deposition processes to form various gate materials, followed by a CMP process to remove excessive gate materials, resulting in the high-k/metal gate structures 180 having top surfaces level with a top surface of the ILD layer 160. Thus, transistors (e.g., GAA FET) are formed, and the high-k/metal gate structure 180 surrounds each of the nanosheets 122 and 125, and thus is referred to as a gate of the transistors (e.g., GAA FET).

The gate dielectric layer 182 may include an interfacial layer and a high-k gate dielectric layer over the interfacial layer. In some embodiments, the interfacial layer is a semiconductor oxide formed on exposed surfaces of semiconductor materials in the gate trenches GT by using, for example, thermal oxidation, chemical oxidation, wet oxidation or the like. As a result, surface portions of the layers 121-125 and the substrate 110 exposed in the gate trenches GT are oxidized into oxides to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 184 includes one or more metal layers. For example, the gate metal layer 184 may include one or more work function metal layers stacked one over another and a fill metal filling up a remainder of gate trenches GT. The one or more work function metal layers in the gate metal layer 184 provide a suitable work function for the high-k/metal gate structures 180. For an n-type GAA FET, the gate metal layer 184 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 184 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 184 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIGS. 15A and 15B. The ILD layer 160 and the dielectric layer 140 are etched to expose a sidewall S1 of the fin FS. For example, a trench opening TH1 is etched in the ILD layer 160 and the dielectric layer 140 to expose sidewall of the layers 121-125 at a first side of the gate structure 180. In some embodiments, prior to etching the trench opening TH1, a patterned mask is formed by photolithography process over the structure of FIGS. 14A and 14B. The photolithography process may include forming a photoresist layer, exposing the photoresist to a pattern, performing post-exposure bake processes, and developing the resist to form a patterned mask including the resist. The patterned mask may be used to protect regions of the substrate 110, and layers formed thereupon during etching the trench opening TH1.

Reference is made to FIG. 16. A selective etching process is performed to remove a portion of the sacrificial semiconductor layer 123 exposed by the trench opening TH1. In some embodiments, the selective etching process may etch materials of the sacrificial semiconductor layer 123 at a faster rate than etch materials of the layers 121, 122, 124, and 125, thus resulting in an openings/space O21 between the bottom source/drain region SDB and the top source/drain region SDT. The selective etching process may include a dry etch, a wet etch, or the combination thereof. In the present embodiments, the selective etching process may use a suitable etch recipe for removing the portions of the sacrificial semiconductor layer 123 (forming the opening O21) without substantially damaging the layers 121, 122, 124, and 125. For example, the selective etching process may be a dry etching process using the fluorine-based gas (e.g. SF₆).

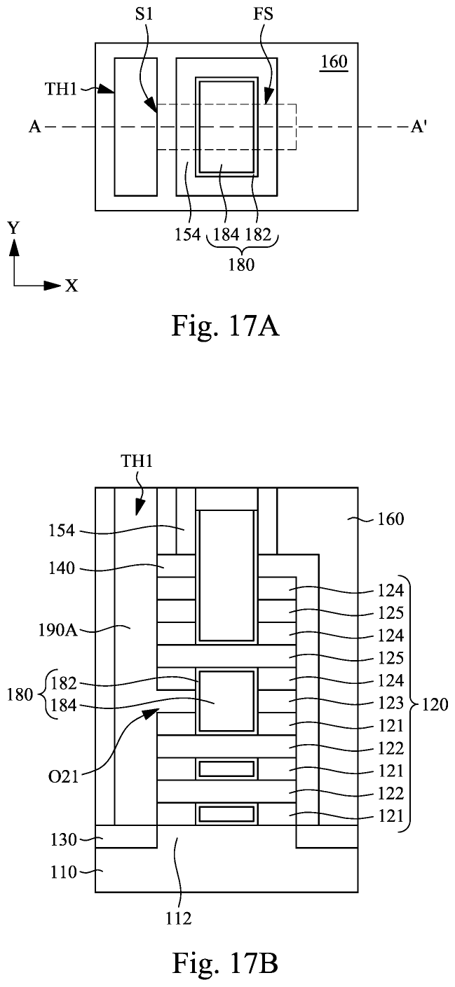

Reference is made to FIGS. 17A and 17B. A dielectric isolation layer 190A is deposited into the opening O21. The dielectric isolation layer 190A may include suitable dielectric materials, such as silicon oxide, silicon oxynitride, and silicon nitride. The deposition process may include ALD, CVD, the like, or the combination thereof. With the presence of the dielectric isolation layer 190A, the two stacked source/drain regions SDB and SDT can be electrically isolated from each other and controlled independently.

In some embodiments, in FIGS. 17A and 17B, the integrated circuit device is formed. One of the source drain regions SDB is electrically isolated from one of the source drain regions SDT, and another one of the source drain regions SDB is electrically connected with another one of the source drain regions SDT, for example, through the doped sacrificial semiconductor layer 123. That is, in the stacked integrated circuit device, one node of the PMOS is electrically connected with one node of NMOS, and another node of the PMOS is electrically isolated from another node of NMOS. This integrated circuit device can be implemented in a Static Random-Access Memory (SRAM) cell. The following steps in FIGS. 18A-20B are optionally performed hereinafter. For example, in some embodiments where it is desired to make the stacked integrated circuit device with on node of the PMOS separated from one node of the NMOS and another node of the PMOS connected with another node of the NMOS, the following steps in FIGS. 18A-20B may be skipped, and contact plugs are then formed. In some embodiments where it is desired to make two nodes of the PMOS are separated from two nodes of the NMOS, the following steps in FIGS. 18A-20B are performed.

Reference is made to FIGS. 18A and 18B. The ILD layer 160 and the dielectric layer 140 are etched to expose a sidewall S2 of the fin FS. For example, a trench opening TH2 is etched in the ILD layer 160 and the dielectric layer 140 to expose sidewall of the layers 121-125 at a second side of the gate structure 180. In some embodiments, prior to etching the trench opening TH2, a patterned mask is formed by photolithography process over the structure of FIGS. 17A and 17B. The photolithography process may include forming a photoresist layer, exposing the photoresist to a pattern, performing post-exposure bake processes, and developing the resist to form a patterned mask including the resist. The patterned mask may be used to protect regions of the substrate 110, and layers formed thereupon during etching the trench opening TH2.

Reference is made to FIG. 19. A selective etching process is performed to remove a portion of the sacrificial semiconductor layer 123 exposed by the trench opening TH2. In some embodiments, the selective etching process may etch materials of the sacrificial semiconductor layer 123 at a faster rate than etch materials of the layers 121, 122, 124, and 125, thus resulting in an openings/space O22 between the bottom source/drain region SDB and the top source/drain region SDT. The selective etching process may include a dry etch, a wet etch, or the combination thereof. In the present embodiments, the selective etching process may use a suitable etch recipe for removing the portions of the sacrificial semiconductor layer 123 (forming the opening O22) without substantially damaging the layers 121, 122, 124, and 125. For example, the selective etching process may be a dry etching process using the fluorine-based gas (e.g. SF₆).

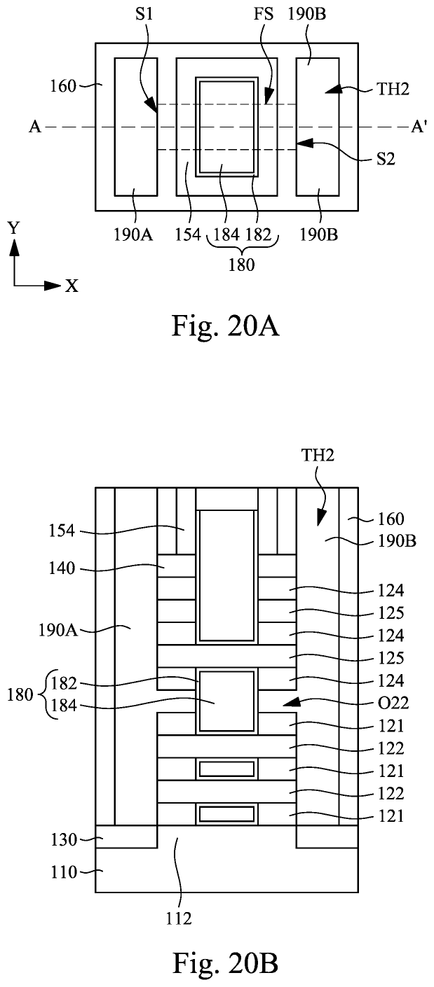

Reference is made to FIGS. 20A and 20B. A dielectric isolation layer 190B is deposited into the opening O22. The dielectric isolation layer 190B may include suitable dielectric materials, such as silicon oxide, silicon oxynitride, and silicon nitride. The deposition process may include ALD, CVD, the like, or the combination thereof. With the presence of the dielectric isolation layer 190B, the two stacked source/drain regions SDB and SDT can be electrically isolated from each other and controlled independently.

Reference is made back to FIGS. 7A and 7B. Contact plugs 212 and 214 may be formed through the interlayer dielectric layer 160, and in contact with the source/drain regions SDB and SDT of the two stacked transistors, respectively. In some embodiments, prior to depositing the conductive material, a dielectric barrier layer 200 is formed for isolating the contact plug 212 from the source/drain regions SDB. Other details of the present embodiments are similar to those illustrated previously, and therefore not repeated herein.

FIGS. 21A and 21B illustrates p-type dopant profiles and levels in an epitaxial stack before and after an annealing process in accordance with some embodiments. The technique of Secondary-ion mass spectrometry (SIMS) is used to analyze the epitaxial stack before and after the annealing process. As shown in FIG. 21A, before the annealing process, the p-type concentration in the SiGe epitaxial stack is in a range from about 4E17 cm⁻³ to ˜2E18 cm⁻³. After the annealing process, as shown in FIG. 21B, the p-type concentration in the SiGe epitaxial stack is in a range from about 1E18 cm⁻³ to ˜3E18 cm⁻³, which is beneficial for forming low source/drain resistance. In FIGS. 21A and 21B, the epitaxial stack comprises doped Ge sacrificial layers and Ge_{0.95}Si_{0.05} channel layers. The semiconductor compositions of the sacrificial layers and the channel layers may change according to fabrication/device requirement. The annealing condition can be optimized for lower S/D resistance according to the semiconductor composition of the epitaxial stack.

In some embodiments, the annealing process may be performed with an annealing temperature ranging from about 250 Celsius degrees to about 1200 Celsius degrees. If the annealing temperature is less than about 250 Celsius degrees, the dopant diffusion may not occur. If the annealing temperature is greater than about 1200 Celsius degrees, the temperature may be higher than a melting point of the semiconductor (e.g., Si). The annealing process may be performed with a time duration greater than about 1 minutes for achieving suitable diffusion performance.

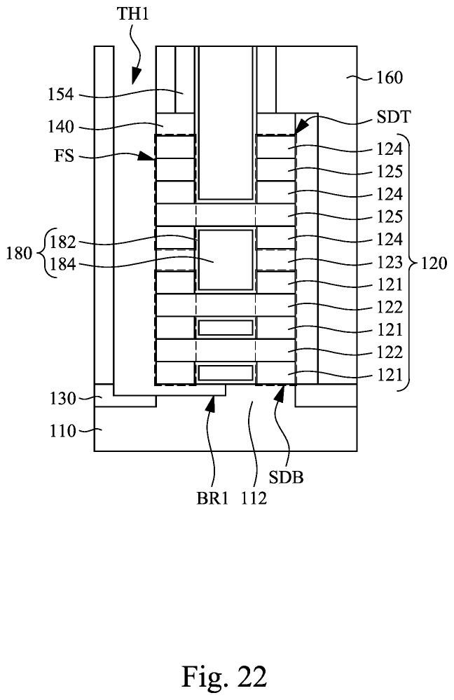

FIGS. 22-25 illustrate a method of manufacturing an integrated circuit device at various stages in accordance with some embodiments. Details of the present embodiments are similar to those illustrated in FIGS. 8A-20B, except that a bottom isolation layer 190AB/190BB is formed below the gate structure 180. With the presence of the isolation layer 190AB/190BB, current leakage from a bottom transistor to the semiconductor substrate may be reduced. It is understood that additional steps may be provided before, during, and after the steps shown in FIGS. 22-25, and some of the steps described below can be replaced or eliminated for additional embodiments of the method. The order of the operations/processes may be interchangeable.

Reference is made to FIG. 22. After the formation of the trench opening TH1 in FIGS. 15A and 15B, a lateral etching process may be performed to remove a top portion of the isolation structure 130 and a top portion of the substrate portion 112, leaving a lateral recess BR1 between the gate structure 180 and the substrate portion 112. Then, the selective etching process in FIG. 16 is performed to form the openings/space O21.

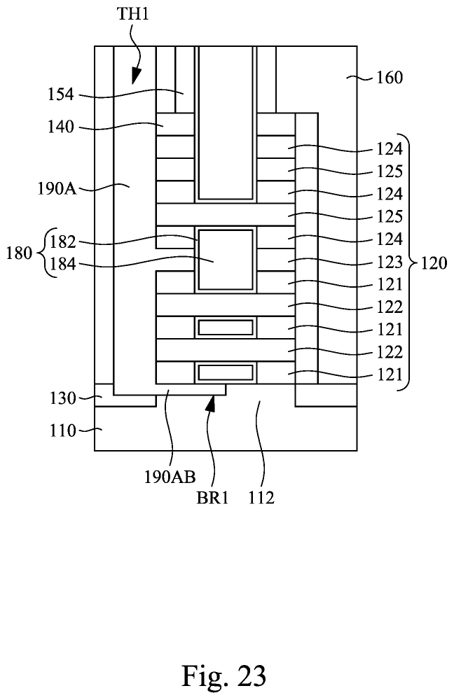

Reference is made to FIG. 23. A dielectric isolation layer 190A is deposited into the opening O21 and the lateral recess BR1, followed by a CMP process to remove an excess portion of the dielectric isolation layer 190A outside the trench opening TH1. The dielectric isolation layer 190A may include a suitable dielectric material, such as silicon oxide, silicon nitride, silicon oxynitride, the like, or the combination thereof. By filling up the lateral recess BR1, the dielectric isolation layer 190A has a bottom isolation layer 190AB between the gate structure 180 and the substrate portion 112 and between one of the source/drain regions SDB of the bottom transistor and the substrate portion 112. The dielectric isolation layer 190A may also fill up the openings/space O21, thereby providing isolation between top and bottom transistors.

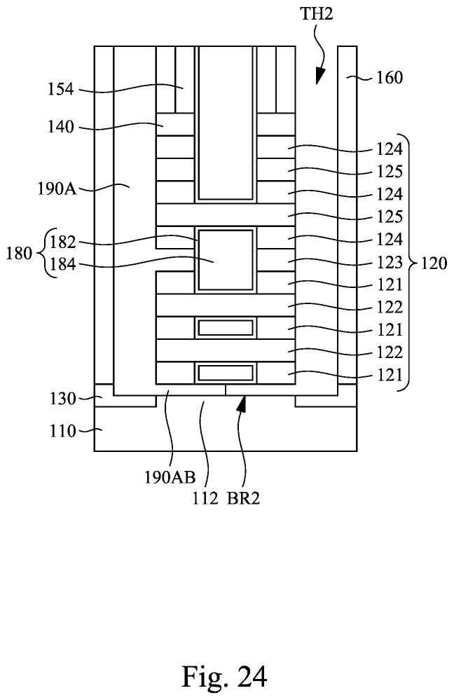

Reference is made to FIG. 24. After the formation of the bottom isolation layer 190AB, the trench opening TH2 is formed as illustrated previously in FIGS. 18A and 18B. Subsequently, after the formation of the trench opening TH2 in FIGS. 18A and 18B, a lateral etching process may be performed to remove a top portion of the isolation structure 130 and a top portion of the substrate portion 112, leaving a lateral recess BR2 between the gate structure 180 and the substrate portion 112. Then, the selective etching process to form the openings/space O22 in FIG. 19 is performed.

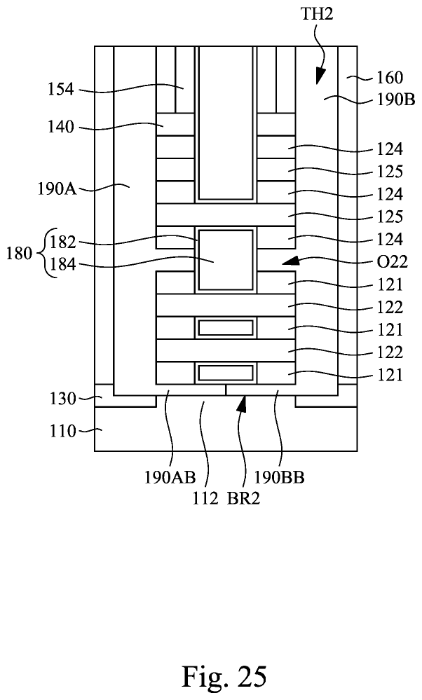

Reference is made to FIG. 25. A dielectric isolation layer 190B is deposited into the opening O22 and the lateral recess BR2, followed by a CMP process to remove an excess portion of the dielectric isolation layer 190B outside the trench opening TH2. The dielectric isolation layer 190B may include a suitable dielectric material, such as silicon oxide, silicon nitride, silicon oxynitride, the like, or the combination thereof. The dielectric isolation layer 190B may include a dielectric material the same or different from that of the dielectric isolation layer 190A. By filling up the lateral recess BR2, the dielectric isolation layer 190B has a bottom isolation layer 190BB between the gate structure 180 and the substrate portion 112 and between the another one of the source/drain regions SDB of the bottom transistor and the substrate portion 112. The dielectric isolation layer 190B may also fill up the openings/space O22, thereby providing isolation between top and bottom transistors. Other details of the present embodiments are similar to those illustrated in FIGS. 8A-20B, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage may be that monolithic transistor stacking with isolated source/drains can be achieved without source/drain regrowth process and complicated etch back process. Another advantage may be the annealing condition can be optimized for lower S/D resistance according to the semiconductor composition of the epitaxial stack.

According to some embodiments of the present disclosure, a method for manufacturing an integrated circuit device is provided. The method includes depositing an epitaxial stack over a substrate, wherein the epitaxial stack comprises a bottom epitaxial stack, a sacrificial semiconductor layer over the bottom epitaxial stack, a top epitaxial stack over the sacrificial semiconductor layer, the bottom epitaxial stack comprises a bottom semiconductor layer and a bottom doped sacrificial layer, and the top epitaxial stack comprises a top semiconductor layer and a top doped sacrificial layer; replacing first portions of the doped bottom sacrificial layer, the sacrificial semiconductor layer, and the top doped sacrificial layer with a gate structure; and replacing a second portion of the sacrificial semiconductor layer with a dielectric isolation layer.

According to some embodiments of the present disclosure, a method for manufacturing an integrated circuit device is provided. The method includes depositing an epitaxial stack over a substrate, wherein the epitaxial stack comprises a bottom epitaxial stack, a sacrificial semiconductor layer over the bottom epitaxial stack, a top epitaxial stack over the sacrificial semiconductor layer, the bottom epitaxial stack comprises a bottom semiconductor layer and a bottom doped sacrificial layer, and the top epitaxial stack comprises a top semiconductor layer and a top doped sacrificial layer; removing first portions of the bottom doped sacrificial layer, the sacrificial semiconductor layer, and the top doped sacrificial layer, while leaving a channel region of the top semiconductor layer and a channel region of the bottom semiconductor layer exposed; performing an annealing process to diffuse dopants in a second portion of the bottom doped sacrificial layer into an peripheral region of the bottom semiconductor layer and diffuse dopants in a second portion of the top doped sacrificial layer into an peripheral region of the top semiconductor layer; and forming a gate structure around the exposed channel region of the top semiconductor layer and the exposed channel region of the bottom semiconductor layer.

According to some embodiments of the present disclosure, an integrated circuit device includes a bottom channel layer, a top channel layer, a gate structure, a first bottom source/drain region, a dielectric isolation layer, and a first top source/drain region. The top channel layer is over and spaced apart from the bottom channel layer. The gate structure wraps around the bottom channel layer and the top channel layer. The first bottom source/drain region is on a side of the bottom channel layer. The dielectric isolation layer is over the first bottom source/drain region. The first top source/drain region is over the dielectric isolation layer and on a side of the top channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an integrated circuit device, comprising:
depositing an epitaxial stack over a substrate, wherein the epitaxial stack comprises a bottom epitaxial stack, a sacrificial semiconductor layer over the bottom epitaxial stack, a top epitaxial stack over the sacrificial semiconductor layer, the bottom epitaxial stack comprises a bottom semiconductor layer and a bottom doped sacrificial layer, and the top epitaxial stack comprises a top semiconductor layer and a top doped sacrificial layer;
replacing first portions of the doped bottom sacrificial layer, the sacrificial semiconductor layer, and the top doped sacrificial layer with a gate structure; and
replacing a second portion of the sacrificial semiconductor layer with a dielectric isolation layer.

2. The method of claim 1, wherein depositing the epitaxial stack is performed such that a germanium concentration of the sacrificial semiconductor layer is greater than a germanium concentration of the top and bottom doped sacrificial layers, and the germanium concentration of the top and bottom doped sacrificial layers is greater than a germanium concentration of the top and bottom semiconductor layers.

3. The method of claim 1, wherein depositing the epitaxial stack is performed such that the bottom doped sacrificial layer is of a first conductive type, and the top doped sacrificial layer is of a second conductive type opposite the first conductive type.

4. The method of claim 1, wherein replacing the first portions of the bottom doped sacrificial layer, the sacrificial semiconductor layer, and the top doped sacrificial layer with the gate structure comprises:
selectively etching the first portions of the bottom doped sacrificial layer, the sacrificial semiconductor layer, and the top doped sacrificial layer, while leaving a channel region of the top semiconductor layer and a channel region of the bottom semiconductor layer exposed; and
forming the gate structure around the exposed channel region of the top semiconductor layer and the exposed channel region of the bottom semiconductor layer.

5. The method of claim 4, wherein selectively etching the first portion of the bottom doped sacrificial layer and the first portion of the top doped sacrificial layer is performed using the same etch recipe.

6. The method of claim 1, further comprising:
performing an annealing process to transform a second portion of the bottom doped sacrificial layer and a peripheral region of the bottom semiconductor layer into a bottom source/drain region and transform a second portion of the top doped sacrificial layer and a peripheral region of the top semiconductor layer into a top source/drain region.

7. The method of claim 6, further comprising:
forming a contact plug over the bottom source/drain region through the dielectric isolation layer.

8. The method of claim 1, further comprising:
after replacing first portions of the doped bottom sacrificial layer, the sacrificial semiconductor layer, and the top doped sacrificial layer with the gate structure, removing a portion of the substrate below the gate structure; and
forming a bottom dielectric isolation layer below the gate structure.

9. A method for manufacturing an integrated circuit device, comprising:
depositing an epitaxial stack over a substrate, wherein the epitaxial stack comprises a bottom epitaxial stack, a sacrificial semiconductor layer over the bottom epitaxial stack, a top epitaxial stack over the sacrificial semiconductor layer, the bottom epitaxial stack comprises a bottom semiconductor layer and a bottom doped sacrificial layer, and the top epitaxial stack comprises a top semiconductor layer and a top doped sacrificial layer;
removing first portions of the bottom doped sacrificial layer, the sacrificial semiconductor layer, and the top doped sacrificial layer, while leaving a channel region of the top semiconductor layer and a channel region of the bottom semiconductor layer exposed;
performing an annealing process to diffuse dopants in a second portion of the bottom doped sacrificial layer into an peripheral region of the bottom semiconductor layer and diffuse dopants in a second portion of the top doped sacrificial layer into an peripheral region of the top semiconductor layer; and
forming a gate structure around the exposed channel region of the top semiconductor layer and the exposed channel region of the bottom semiconductor layer.

10. The method of claim 9, wherein the annealing process is performed prior to forming the gate structure.

11. The method of claim 9, further comprising:
forming a first contact plug on the peripheral region of the bottom semiconductor layer, wherein the first contact plug extends through the peripheral region of the top semiconductor layer.

12. The method of claim 11, further comprising:
forming a dielectric barrier layer spacing apart the first contact plug from the peripheral region of the top semiconductor layer.

13. The method of claim 11, further comprising:
forming a second contact plug on the peripheral region of the top semiconductor layer, wherein the second contact plug is closer to the gate structure than the first contact plug.

14. The method of claim 9, wherein depositing the epitaxial stack is performed such that the bottom doped sacrificial layer is of a first conductive type, and the top doped sacrificial layer is of a second conductive type opposite the first conductive type.

15. The method of claim 9, further comprising:
replacing a second portion of the sacrificial semiconductor layer with a dielectric isolation layer.

16. An integrated circuit device, comprising:
a bottom channel layer;
a top channel layer over and spaced apart from the bottom channel layer; and
a gate structure wrapping around the bottom channel layer and the top channel layer; and
a first bottom source/drain region on a side of the bottom channel layer;
an isolation layer over the first bottom source/drain region; and
a first top source/drain region over the isolation layer and on a side of the top channel layer.

17. The integrated circuit device of claim 16, further comprising:
another isolation layer below the gate structure and the first bottom source/drain region.

18. The integrated circuit device of claim 16, wherein the first bottom source/drain region has a first doped semiconductor layer and a second doped semiconductor layer, the first doped semiconductor layer has a same material as that of the bottom channel layer, and the second doped semiconductor layer has a different material than that of the bottom channel layer.

19. The integrated circuit device of claim 16, wherein the isolation layer has a void therein.

20. The integrated circuit device of claim 16, further comprising:
a second bottom source/drain region on another side of the bottom channel layer; and
a second top source/drain region over the second bottom source/drain region and on another side of the top channel layer.
